(19) United States
(12) Patent Application Publication
(10) Pub. No.: US 2026/0039314 A1
(43) Pub. Date: Feb. 5, 2026

(54) FAILURE MODE-ADAPTIVE LOW-DENSITY PARITY CHECK SOFT DECODING

(71) Applicant: Micron Technology, Inc., Boise, ID (US)

(72) Inventors: Li-Te CHANG, San Jose, CA (US); Tingjun XIE, Milpitas, CA (US); Murong LANG, San Jose, CA (US)

(21) Appl. No.: 19/231,224

(22) Filed: Jun. 6, 2025

Related U.S. Application Data
(60) Provisional application No. 63/678,091, filed on Aug. 1, 2024.

(51) Int. Cl. H03M 13/11

(52) U.S. Cl. CPC H03M 13/1108

(57) ABSTRACT

In some implementations, a device may receive a data signal from a memory device. The device may perform a low-density parity check (LDPC) hard bit decoding on the data signal to identify a plurality of hard bit read positions (HBRPs). The device may identify, with a machine learning model using the plurality of HBRPs, a failure mode of the memory device. The device may identify a set of parameters for an LDPC soft bit decoding based on the failure mode. The device may perform the LDPC soft bit decoding on the data signal using the set of parameters.

### TECHNICAL FIELD

This Patent Application claims priority to U.S. Provisional Patent Application No. 63/678,091, filed on Aug. 1, 2024, entitled “FAILURE MODE-ADAPTIVE LOW-DENSITY PARITY CHECK SOFT DECODING,” and assigned to the assignee hereof. The disclosure of the prior Application is considered part of and is incorporated by reference into the Patent Application.

### TECHNICAL FIELD

The present disclosure generally relates to memory devices, memory device operations, and, for example, to failure mode-adaptive low-density parity check (LDPC) soft decoding.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of failure mode-adaptive low-density parity check (LDPC) soft decoding.

FIG. 2 is a diagram of an example of LDPC soft decoding.

FIG. 3 is a diagram of an example of training a machine learning model for failure mode-adaptive LDPC soft decoding.

FIG. 4 is a diagram of an example of failure mode-adaptive LDPC soft decoding.

FIG. 5 is a flowchart of an example method associated with failure mode-adaptive LDPC soft decoding.

FIG. 6 is a flowchart of an example method associated with training a machine learning model for failure mode-adaptive LDPC soft decoding.

### DETAILED DESCRIPTION

A host device may utilize read error handling in connection with data retrieval from a memory device. Read error handling may include the processing of a data signal by performing a series of iterations with low-density parity check (LDPC) hard bit decoding, followed sequentially by a series of iterations with LDPC soft bit decoding. In hard bit decoding, binary data received from memory cells is decoded using parity-check equations to identify and correct errors based on hard (binary) decisions without considering the reliability of each bit. In soft bit decoding, data is decoded by considering the probabilistic reliability of each bit, allowing for more accurate error correction by leveraging soft (non-binary) information about the bit values from memory cells. As such, soft bit decoding may use significant processing resources and experience additional latency. To reduce the processing burden and latency, some soft bit decoding schemes may use fixed values for soft bit read positions (SBRPs) and log likelihood ratios (LLRs) used for soft bit decoding. However, these fixed values may be suboptimal, thereby degrading soft decoding performance, as they do not account for the dynamic nature of memory devices and the various failure modes encountered by memory devices.

Some implementations described herein enable efficient, low-latency identification of optimal soft bit read (SBR) parameters (e.g., SBRPs and LLRs) for LDPC soft bit decoding. Techniques described herein may use a machine learning model that is trained from hard bit read position (HBRP) data derived using memory devices subjected to different failure modes (e.g., high-temperature data retention (HTDR), long-term data retention, read/write cross-temperature effects, read disturb errors, or the like) through stress conditions. The HBRP data may indicate optimal HBRPs at different threshold voltage levels under different failure modes. Moreover, the SBR parameters derived using the memory devices under the different failure modes can be recorded in a mapping (e.g., the mapping indicates the optimal SBR parameters for each failure mode). The machine learning model and the mapping may be stored in a device (e.g., a host device controller) for use in read error handling.

For example, when reading data from a memory device, the device may initiate read error handling by performing an LDPC hard bit decoding on the data. Through the hard bit decoding, the device may identify HBRPs for multiple threshold voltage levels that represent different memory cell states. Using the HBRPs as an input to the machine learning model, the device may identify a failure mode of the memory device that is indicated by the HBRPs. The device may then use the mapping to identify SBR parameters that are to be applied under the failure mode. Furthermore, in connection with the error handling, the device may perform an LDPC soft bit decoding on the data using the SBR parameters. In this way, the device performs the LDPC soft bit decoding using dynamic SBR parameters that are tailored to enhance LDPC soft bit decoding efficiency under the failure mode experienced by the memory device. Therefore, techniques described herein improve error correction performance, reduce latency, and enhance system throughput.

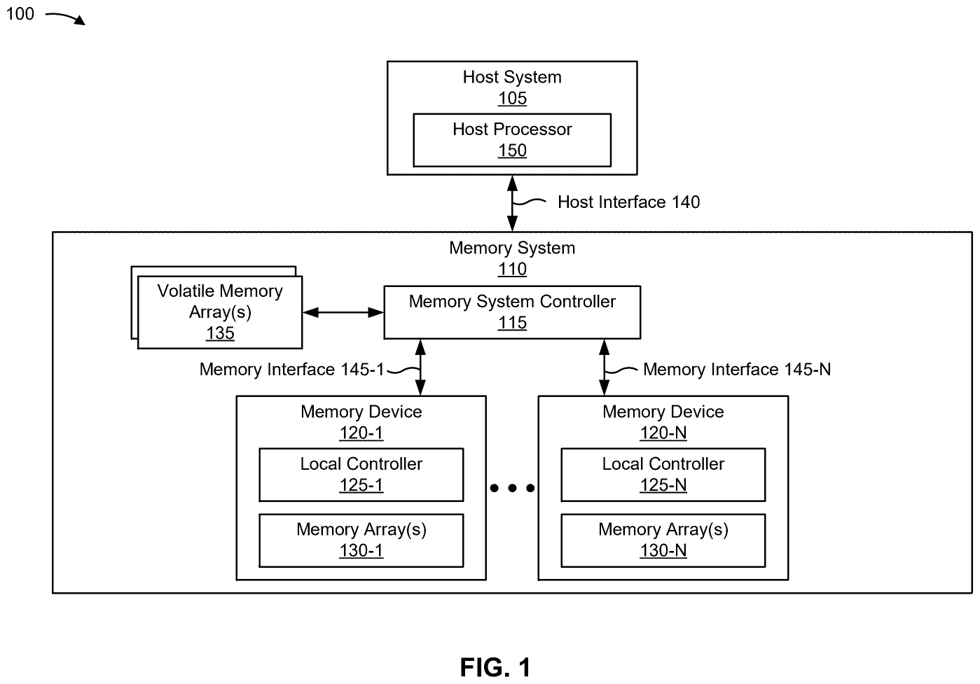

FIG. 1 is a diagram illustrating an example system 100 capable of failure mode-adaptive LDPC soft decoding. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to perform an LDPC hard bit decoding on a data signal from a memory device to identify respective HBRPs for a plurality of threshold voltage levels associated with memory cells in the memory device; identify, with a machine learning model using the respective HBRPs, a failure mode of the memory device; identify a set of parameters for an LDPC soft bit decoding based on the failure mode, where the set of parameters indicates a plurality of SBRPs and a plurality of LLR values; and perform the LDPC soft bit decoding on the data signal using the set of parameters.

In some implementations, one or more systems, devices, apparatuses, components, and/or controllers of FIG. 1 may be configured to receive a data signal from a memory device; perform an LDPC hard bit decoding on the data signal to identify a plurality of HBRPs; identify, with a machine learning model using the plurality of HBRPs, a failure mode of the memory device; identify a set of parameters for an LDPC soft bit decoding based on the failure mode; and perform the LDPC soft bit decoding on the data signal using the set of parameters.

In some implementations, one or more systems, devices, apparatuses, components, and/or controllers of FIG. 1 may be configured to receive a data signal from a memory device; detect one or more errors in the data signal; perform, responsive to detection of the one or more errors, an LDPC hard bit decoding on the data signal to identify respective HBRPs for a plurality of threshold voltage levels associated with memory cells in the memory device; identify, with a machine learning model using the respective HBRPs, a failure mode of the memory device; identify a set of parameters for an LDPC soft bit decoding based on the failure mode, where the set of parameters indicates a plurality of SBRPs and a plurality of LLR values; and perform the LDPC soft bit decoding on the data signal using the set of parameters.

In some implementations, one or more systems, devices, apparatuses, components, and/or controllers of FIG. 1 may be configured to obtain threshold voltage data from a memory device subjected to stress conditions to simulate a failure mode; identify a plurality of HBRPs for a plurality of voltage valleys defined by the threshold voltage data; and train a machine learning model to classify the failure mode using the plurality of HBRPs labeled as being associated with the failure mode.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

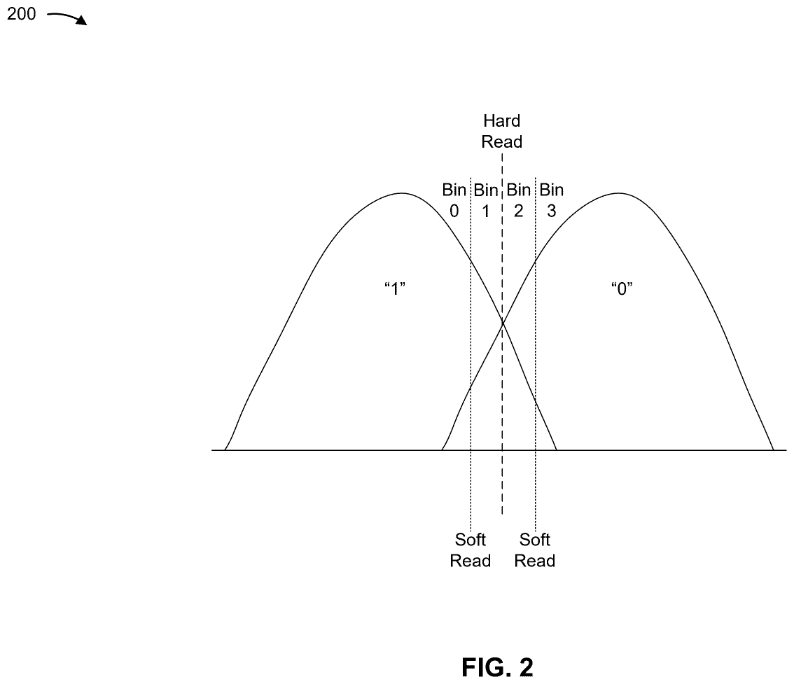

FIG. 2 is a diagram of an example 200 of LDPC soft decoding. LDPC soft decoding can recover reliability errors using a one-hard-one-soft (1H1S) scheme (e.g., in a NAND system) that uses one hard read strobe and two soft read strobes. Here, each bit being decoded may be classified into one of four bins (shown in FIG. 2 as Bin 0, Bin 1, Bin 2, and Bin 3), and each bin has a corresponding LLR that is a measure of probability for the bit's original program state. For example, a soft read may not be used directly in LDPC soft decoding, but a corresponding LLR may provide a confidence to decode. The hard read may determine a hard bit, and the two soft reads may determine a soft bit (e.g., as a result of an XOR operation on the first and second soft reads). One approach used in LDPC soft decoding is to pursue a maximum mutual information (MI), where MI is a function of the hard and soft read strobes. Mutual information may be defined as a measure of information that one random variable X contains about another random variable Y.

As indicated above, FIG. 2 is provided as an example. Other examples may differ from what is described with regard to FIG. 2.

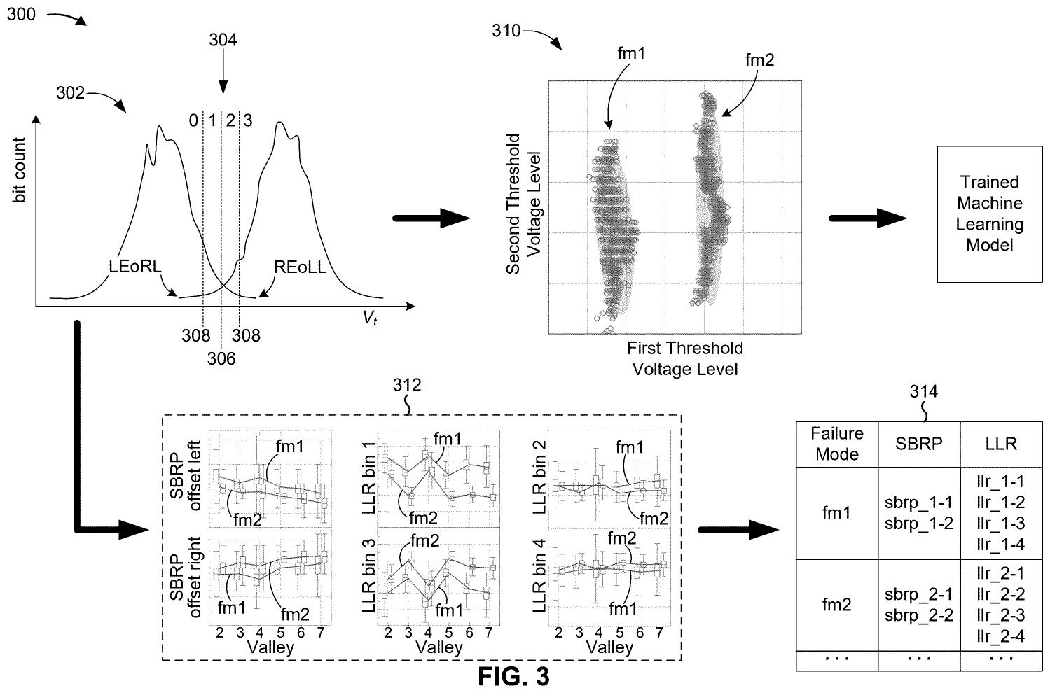

FIG. 3 is a diagram of an example 300 of training a machine learning model for failure mode-adaptive LDPC soft decoding. The operations of example 300 may be performed by a machine learning system, which may include one or more devices used to generate training data for the machine learning model and/or used to train the machine learning model. In some implementations, the machine learning system may be, or may include, the host system 105 and/or one or more components of the host system 105, such as the host processor 150.

The machine learning model may be trained to classify multiple failure modes associated with memory devices based on HBRP data. In some implementations, the machine learning model is a classification model trained with supervised learning. For example, the machine learning model may be a decision tree model, a support vector machine (SVM) model, a random forest model, a k-nearest neighbors (KNN) model, a logistic regression model, or a neural network.

The machine learning system may derive training data for the machine learning model using one or more memory devices (e.g., hundreds or thousands of memory devices) that are subjected to stress conditions (e.g., using temperature) to simulate different failure modes. For example, the failure modes may include an HTDR failure mode, a long-term data retention failure mode, a read/write cross-temperature effect failure mode (e.g., data is written under one temperature extreme and read under a different temperature extreme), a read disturb errors failure mode, or the like. Using the knowledge of a failure mode that is being simulated by a memory device, the training data can be labeled for use in supervised learning.

As an example, the machine learning system may obtain threshold voltage (Vₜ) data 302 from a memory device simulating a particular failure mode. The threshold voltage data 302 may define a plurality of voltage valleys 304 (one shown in FIG. 3). The machine learning system may select one of the voltage valleys 304, and identify an HBRP 306 for the voltage valley 304. The HBRP 306 may be an optimal HBRP, which may refer to an HBRP that minimizes a raw bit error rate (RBER). In particular, the machine learning system may obtain a pair of threshold voltage data 302, as shown, which defines one voltage valley 304. In some implementations, the machine learning system may clean the threshold voltage data 302. To identify the HBRP 306, the machine learning system may iteratively adjust a position of a candidate HBRP in the voltage valley 304 to obtain a minimum RBER. In particular, using the threshold voltage data 302, the machine learning system may identify a candidate HBRP within a range of a left edge of right level (LEoRL) and a right edge of left level (REoLL) associated with the voltage valley 304, and the machine learning system may compute a fail bit count (FBC) for that candidate HBRP (e.g., a sum of bit count in a left region to the HBRP and a bit count in a right region to the HBRP). The machine learning system may perform one or more iterations of this procedure, each iteration slightly moving the position of the candidate HBRP, until the HBRP 306 with a minimum FBC is found.

Once the optimal HBRP 306 is identified, the machine learning system may identify SBRPs 308 with respect to the HBRP 306 (e.g., as offsets with respect to the HBRP 306). The SBRPs 308 may be optimal SBRPs that maximize mutual information. The HBRP 306 and the SBRPs 308 may define multiple voltage bins (e.g., four voltage bins, labeled 0 through 3), and the machine learning system may compute respective LLRs for each bin (e.g., based on the HBRP 306 and the SBRPs 308). This procedure may be performed for each voltage valley 304 of the threshold voltage data 302. In this way, for each memory device simulating a particular failure mode, the machine learning system may generate data (e.g., silicon data, rather than simulated data) indicating an optimal HBRP and optimal SBR parameters (e.g., SBRPs and LLRs), for that failure mode, for each of a plurality of threshold voltage levels.

HBRP data 310 for the memory devices may be labeled by failure mode and used by the machine learning system to train the machine learning model to classify failure modes based on HBRP data. For example, a first failure mode (fm1) may be associated with HBRPs for a plurality of threshold voltage levels (shown as a “first threshold voltage level” along an x-axis and a “second threshold voltage level” along a y-axis) that form a first cluster, and a second failure mode (fm2) may be associated with HBRPs for the plurality of threshold voltage levels that form a second cluster. As an example, an HTDR failure mode may be associated with a lower HBRP at threshold voltage level L1 and a lower HBRP at threshold voltage level L7, while a read disturb errors failure mode may be associated with a higher HBRP at threshold voltage level L1 and a higher HBRP at threshold voltage level L7. SBR parameters 312, per failure mode (e.g., fm1 and fm2), may be aggregated (e.g., the SBRPs and LLRs, per failure mode, may be averaged). The machine learning system may generate a mapping 314 (e.g., a look-up table) that maps failure modes to SBR parameters.

As indicated above, FIG. 3 is provided as an example. Other examples may differ from what is described with regard to FIG. 3.

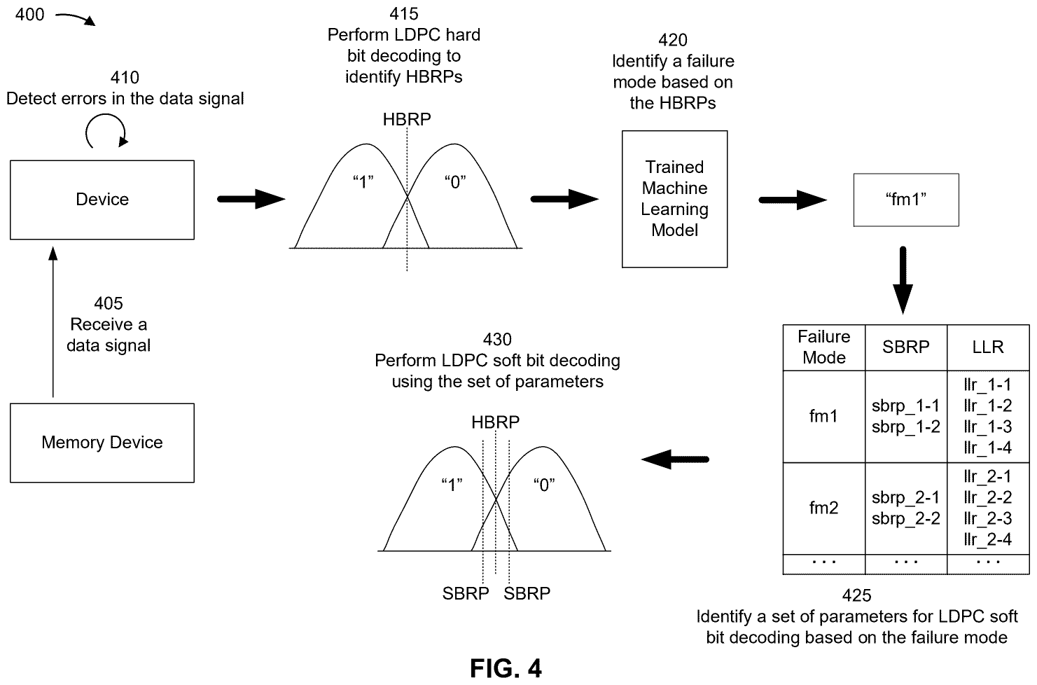

FIG. 4 is a diagram of an example 400 of failure mode-adaptive LDPC soft decoding. The operations described in connection with FIG. 4 may be performed by a device, such as the host system 105 and/or one or more components of the host system 105, such as the host processor 150. The device may store the trained machine learning model and the mapping described in connection with FIG. 3. For example, the machine learning model and the mapping may be implemented in memory device firmware that is implemented by the device.

As shown by reference number 405, the device may receive a data signal from a memory device. For example, the device may issue a read command to the memory device, and the device may receive the data signal in response to the read command. The memory device may include triple-level cell (TLC), quadruple-level cell (QLC), or greater, NAND memory.

In some examples, the memory device may be operating under a failure mode, resulting in errors in the data signal (e.g., discrepancies between stored data and retrieved data, such as uncertain bits due to channel noise or degradation of the memory device). As shown by reference number 410, the device may detect errors in the data signal. For example, the device may detect errors in the data signal using an error detection technique, such as a cyclic redundancy check (CRC), a parity check, or the like. Responsive to detection of the errors, the device may initiate a read error handling procedure that includes LDPC hard bit decoding and LDPC soft bit decoding.

As shown by reference number 415, in connection with the read error handling procedure, the device may perform LDPC hard bit decoding to identify respective HBRPs for a plurality of threshold voltage levels associated with memory cells in the memory device. For example, the device may perform multiple iterations of the LDPC hard bit decoding to identify a best HBRP, in a similar manner as described in connection with FIG. 3. In connection with performing the LDPC hard bit decoding, the device may also determine one or more hard bits of the data signal.

Each threshold voltage level may represent different memory cell states (e.g., where each state represents a combination of bits). As described herein, an HBRP represents a point in a voltage valley where a line can be placed for hard bit discrimination, specifying whether a memory cell's threshold voltage indicates a “0” or a “1” state. In some implementations, the threshold voltage levels include at least seven threshold voltage levels (e.g., referred to as L1, L2, L3, L4, L5, L6, and L7). In some implementations, the threshold voltage levels include at least two threshold voltage levels. In some implementations, the threshold voltage levels may include only two threshold voltage levels having a largest separation from each other among threshold voltage levels (e.g., L1 and L7).

As shown by reference number 420, the device may identify a failure mode of the memory device based on the HBRPs. For example, the device may identify the failure mode using at least two HBRPs. The device may identify the failure mode with the machine learning model using the HBRPs (e.g., the device may input the HBRPs to the machine learning model, and the machine learning model may output the failure mode). For example, the machine learning model may classify the HBRPs as being indicative of the failure mode. As shown in example 400, the machine learning model may classify the HBRPs as being indicative of failure mode “fm1.”

As shown by reference number 425, the device may identify a set of parameters for LDPC soft bit decoding (also being referred to herein as “SBR parameters”) based on the identified failure mode. The device may identify the SBR parameters, based on the failure mode, using the mapping of failure modes to SBR parameters, described herein. For example, the device may identify the SBR parameters, based on the failure mode, using a look-up table. As described herein, the SBR parameters may include a plurality of SBRPs (e.g., two SBRPs per HBRP), and a plurality of LLR values. In some implementations, the SBRPs may be represented as offsets from an HBRP. As described herein, an HBRP for a threshold voltage level, and SBRPs (e.g., two SBRPs), may define a plurality of voltage bins (e.g., four voltage bins), and the LLR values may correspond respectively to the voltage bins. As described herein, the SBRPs (e.g., which were derived using memory devices simulating the failure mode) may provide maximized mutual information for LDPC soft decoding.

As shown by reference number 430, the device may perform LDPC soft bit decoding on the data signal using the SBR parameters. For example, the device may perform the LDPC soft bit decoding using the SBRPs and the LLR values. In connection with performing the LDPC soft bit decoding, the device may determine one or more soft bits of the data signal. Based on performing the LDPC soft decoding, the device may recover the bits of the data signal (e.g., based on hard and soft bits that are determined). Techniques described herein reduce the latency associated with LDPC soft bit decoding while also facilitating flexibility in applying failure-targeted SBR settings, thereby leading to improved read error handling, read quality, and performance.

As indicated above, FIG. 4 is provided as an example. Other examples may differ from what is described with regard to FIG. 4.

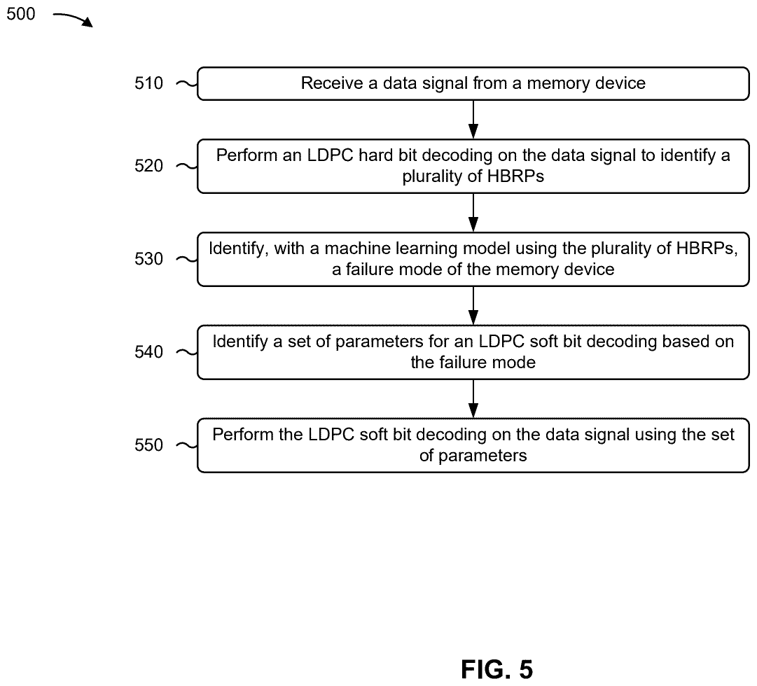

FIG. 5 is a flowchart of an example method 500 associated with failure mode-adaptive LDPC soft decoding. In some implementations, a device (e.g., the host system 105) may perform or may be configured to perform the method 500. Additionally, or alternatively, one or more components of the device (e.g., the host processor 150) may perform or may be configured to perform the method 500. Thus, means for performing the method 500 may include the device and/or one or more components of the device. Additionally, or alternatively, a non-transitory computer-readable medium may store one or more instructions that, when executed by the device, cause the device to perform the method 500.

As shown in FIG. 5, the method 500 may include receiving a data signal from a memory device (block 510). As further shown in FIG. 5, the method 500 may include performing an LDPC hard bit decoding on the data signal to identify a plurality of HBRPs (block 520). As further shown in FIG. 5, the method 500 may include identifying, with a machine learning model using the plurality of HBRPs, a failure mode of the memory device (block 530). As further shown in FIG. 5, the method 500 may include identifying a set of parameters for an LDPC soft bit decoding based on the failure mode (block 540). As further shown in FIG. 5, the method 500 may include performing the LDPC soft bit decoding on the data signal using the set of parameters (block 550).

The method 500 may include additional aspects, such as any single aspect or any combination of aspects described below and/or described in connection with one or more other methods or operations described elsewhere herein.
In a first aspect, the set of parameters indicates a plurality of SBRPs and a plurality of LLR values.
In a second aspect, alone or in combination with the first aspect, the plurality of SBRPs and the plurality of LLR values are averaged values derived using multiple memory devices subjected to stress conditions to simulate the failure mode.
In a third aspect, alone or in combination with one or more of the first and second aspects, identifying the set of parameters includes identifying the set of parameters, based on the failure mode, using a mapping of failure modes to sets of parameters.
In a fourth aspect, alone or in combination with one or more of the first through third aspects, the set of parameters is based on data derived using one or more memory devices subjected to stress conditions to simulate the failure mode.
In a fifth aspect, alone or in combination with one or more of the first through fourth aspects, the machine learning model is a classification model trained with supervised learning.
In a sixth aspect, alone or in combination with one or more of the first through fifth aspects, the machine learning model is trained from HBRP data derived using one or more memory devices subjected to stress conditions to simulate different failure modes.
In a seventh aspect, alone or in combination with one or more of the first through sixth aspects, the machine learning model is trained to classify multiple failure modes based on HBRP data.
In an eighth aspect, alone or in combination with one or more of the first through seventh aspects, the plurality of threshold voltage levels include at least seven threshold voltage levels.
In a ninth aspect, alone or in combination with one or more of the first through eighth aspects, an HBRP, of the respective HBRPs, for a threshold voltage level, of the plurality of threshold voltage levels, and the plurality of SBRPs define a plurality of voltage bins, and the plurality of LLR values correspond respectively to the plurality of voltage bins.
In a tenth aspect, alone or in combination with one or more of the first through ninth aspects, the method 500 includes detecting one or more errors in the data signal, and initiating, responsive to detection of the one or more errors, a read error handling procedure that includes the LDPC hard bit decoding and the LDPC soft bit decoding.
In an eleventh aspect, alone or in combination with one or more of the first through tenth aspects, the memory device includes triple-level cell NAND memory or quadruple-level cell NAND memory.
In a twelfth aspect, alone or in combination with one or more of the first through eleventh aspects, the failure mode is a high-temperature data retention failure mode, a long-term data retention failure mode, a cross-temperature effect failure mode, or a read disturb errors failure mode.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

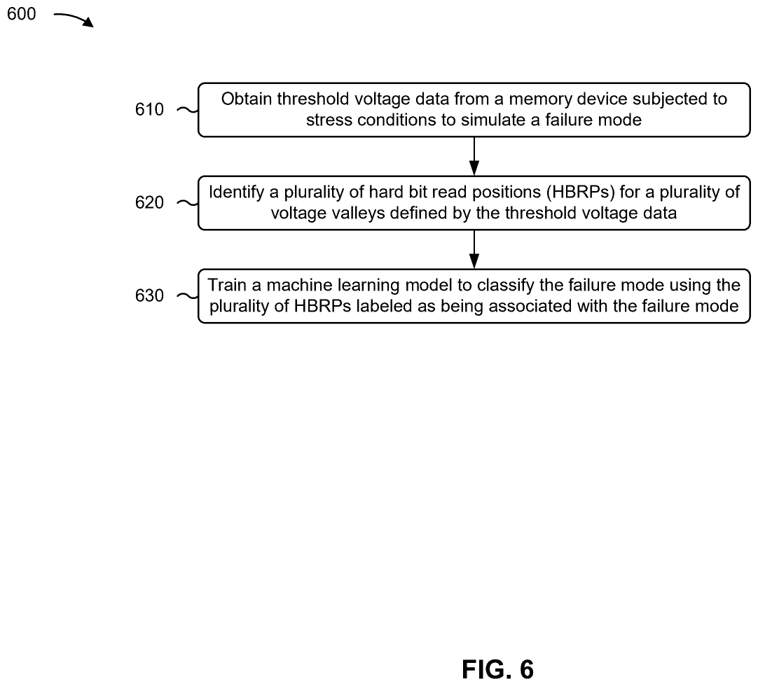

FIG. 6 is a flowchart of an example method 600 associated with training a machine learning model for failure mode-adaptive LDPC soft decoding. In some implementations, a machine learning system (e.g., the host system 105) may perform or may be configured to perform the method 600. Additionally, or alternatively, one or more components of the machine learning system (e.g., the host processor 150) may perform or may be configured to perform the method 600. Thus, means for performing the method 600 may include the machine learning system and/or one or more components of the machine learning system. Additionally, or alternatively, a non-transitory computer-readable medium may store one or more instructions that, when executed by the machine learning system, cause the machine learning system to perform the method 600.

As shown in FIG. 6, the method 600 may include obtaining threshold voltage data from a memory device subjected to stress conditions to simulate a failure mode (block 610). As further shown in FIG. 6, the method 600 may include identifying a plurality of HBRPs for a plurality of voltage valleys defined by the threshold voltage data (block 620). As further shown in FIG. 6, the method 600 may include training a machine learning model to classify the failure mode using the plurality of HBRPs labeled as being associated with the failure mode (block 630).

The method 600 may include additional aspects, such as any single aspect or any combination of aspects described below and/or described in connection with one or more other methods or operations described elsewhere herein.
In a first aspect, the plurality of HBRPs minimize a raw bit error rate.
In a second aspect, alone or in combination with the first aspect, identifying the plurality of HBRPs includes iteratively adjusting an HBRP, of the plurality of HBRPs, in a voltage valley, of the plurality of voltage valleys, to obtain a minimum raw bit error rate.
In a third aspect, alone or in combination with one or more of the first and second aspects, the method 600 includes identifying a plurality of SBRPs for the plurality of voltage valleys, and computing respective LLR values for a plurality of voltage bins defined by at least one of the plurality of HBRPs and at least one of the plurality of SBRPs, where the plurality of SBRPs and the respective LLR values define a set of parameters for LDPC soft bit decoding.
In a fourth aspect, alone or in combination with one or more of the first through third aspects, the plurality of SBRPs maximize mutual information.
In a fifth aspect, alone or in combination with one or more of the first through fourth aspects, the method 600 includes generating a mapping of the set of parameters to the failure mode.
In a sixth aspect, alone or in combination with one or more of the first through fifth aspects, training the machine learning model includes training the machine learning model to classify multiple failure modes based on HBRP data.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a device includes one or more components configured to: perform an LDPC hard bit decoding on a data signal from a memory device to identify respective HBRPs for a plurality of threshold voltage levels associated with memory cells in the memory device; identify, with a machine learning model using the respective HBRPs, a failure mode of the memory device; identify a set of parameters for an LDPC soft bit decoding based on the failure mode, wherein the set of parameters indicates a plurality of SBRPs and a plurality of LLR values; and perform the LDPC soft bit decoding on the data signal using the set of parameters.

In some implementations, a method includes receiving a data signal from a memory device; performing an LDPC hard bit decoding on the data signal to identify a plurality of HBRPs; identifying, with a machine learning model using the plurality of HBRPs, a failure mode of the memory device; identifying a set of parameters for an LDPC soft bit decoding based on the failure mode; and performing the LDPC soft bit decoding on the data signal using the set of parameters.

In some implementations, a system includes a memory device; and a host device configured to: receive a data signal from the memory device; perform an LDPC hard bit decoding on the data signal to identify a plurality of HBRPs; identify, with a machine learning model using the plurality of HBRPs, a failure mode of the memory device; identify a set of parameters for an LDPC soft bit decoding based on the failure mode; and perform the LDPC soft bit decoding on the data signal using the set of parameters.

In some implementations, an apparatus includes means for receiving a data signal from a memory device; means for detecting one or more errors in the data signal; means for performing, responsive to detection of the one or more errors, an LDPC hard bit decoding on the data signal to identify respective HBRPs for a plurality of threshold voltage levels associated with memory cells in the memory device; means for identifying, with a machine learning model using the respective HBRPs, a failure mode of the memory device; means for identifying a set of parameters for an LDPC soft bit decoding based on the failure mode, where the set of parameters indicates a plurality of SBRPs and a plurality of LLR values; and means for performing the LDPC soft bit decoding on the data signal using the set of parameters.

In some implementations, a method includes obtaining threshold voltage data from a memory device subjected to stress conditions to simulate a failure mode; identifying a plurality of HBRPs for a plurality of voltage valleys defined by the threshold voltage data; and training a machine learning model to classify the failure mode using the plurality of HBRPs labeled as being associated with the failure mode.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same clement (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A device, comprising:
one or more components configured to:
perform a low-density parity check (LDPC) hard bit decoding on a data signal from a memory device to identify respective hard bit read positions (HBRPs) for a plurality of threshold voltage levels associated with memory cells in the memory device;
identify, with a machine learning model using the respective HBRPs, a failure mode of the memory device;
identify a set of parameters for an LDPC soft bit decoding based on the failure mode,
wherein the set of parameters indicates a plurality of soft bit read positions (SBRPs) and a plurality of log likelihood ratio (LLR) values; and
perform the LDPC soft bit decoding on the data signal using the set of parameters.

2. The device of claim 1, wherein the one or more components, to identify the set of parameters, are configured to:
identify the set of parameters, based on the failure mode, using a mapping of failure modes to sets of parameters.

3. The device of claim 1, wherein the set of parameters is based on data derived using one or more memory devices subjected to stress conditions to simulate the failure mode.

4. The device of claim 1, wherein the plurality of SBRPs and the plurality of LLR values are averaged values derived using multiple memory devices subjected to stress conditions to simulate the failure mode.

5. The device of claim 1, wherein the machine learning model is a classification model trained with supervised learning.

6. The device of claim 1, wherein the machine learning model is trained from HBRP data derived using one or more memory devices subjected to stress conditions to simulate different failure modes.

7. The device of claim 1, wherein the machine learning model is trained to classify multiple failure modes based on HBRP data.

8. The device of claim 1, wherein the plurality of threshold voltage levels include at least seven threshold voltage levels.

9. The device of claim 1, wherein an HBRP, of the respective HBRPs, for a threshold voltage level, of the plurality of threshold voltage levels, and the plurality of SBRPs define a plurality of voltage bins, and
wherein the plurality of LLR values correspond respectively to the plurality of voltage bins.

10. The device of claim 1, wherein the one or more components are further configured to:
detect one or more errors in the data signal; and
initiate, responsive to detection of the one or more errors, a read error handling procedure that includes the LDPC hard bit decoding and the LDPC soft bit decoding.

11. The device of claim 1, wherein the memory device includes triple-level cell NAND memory or quadruple-level cell NAND memory.

12. The device of claim 1, wherein the failure mode is a high-temperature data retention failure mode, a long-term data retention failure mode, a cross-temperature effect failure mode, or a read disturb errors failure mode.

13. A method, comprising:
receiving a data signal from a memory device;
performing a low-density parity check (LDPC) hard bit decoding on the data signal to identify a plurality of hard bit read positions (HBRPs);
identifying, with a machine learning model using the plurality of HBRPs, a failure mode of the memory device;
identifying a set of parameters for an LDPC soft bit decoding based on the failure mode; and
performing the LDPC soft bit decoding on the data signal using the set of parameters.

14. The method of claim 13, wherein the set of parameters indicates a plurality of soft bit read positions (SBRPs) and a plurality of log likelihood ratio (LLR) values.

15. The method of claim 13, wherein the set of parameters is based on data derived using one or more memory devices subjected to stress conditions to simulate the failure mode.

16. The method of claim 13, wherein the machine learning model is trained from HBRP data derived using one or more memory devices subjected to stress conditions to simulate different failure modes.

17. The method of claim 13, further comprising:
detecting one or more errors in the data signal; and
initiating, responsive to detection of the one or more errors, a read error handling procedure that includes the LDPC hard bit decoding and the LDPC soft bit decoding.

18. The method of claim 13, wherein the failure mode is a high-temperature data retention failure mode, a long-term data retention failure mode, a cross-temperature effect failure mode, or a read disturb errors failure mode.

19. A system, comprising:
a memory device; and
a host device configured to:
receive a data signal from the memory device;
perform a low-density parity check (LDPC) hard bit decoding on the data signal to identify a plurality of hard bit read positions (HBRPs);
identify, with a machine learning model using the plurality of HBRPs, a failure mode of the memory device;
identify a set of parameters for an LDPC soft bit decoding based on the failure mode; and
perform the LDPC soft bit decoding on the data signal using the set of parameters.

20. The system of claim 19, wherein the set of parameters indicates a plurality of soft bit read positions (SBRPs) and a plurality of log likelihood ratio (LLR) values.

21. The system of claim 19, wherein the set of parameters is based on data derived using one or more memory devices subjected to stress conditions to simulate the failure mode.

22. The system of claim 19, wherein the machine learning model is a classification model trained with supervised learning.

23. The system of claim 19, wherein the memory device includes triple-level cell NAND memory or quadruple-level cell NAND memory.

24. The system of claim 19, wherein the failure mode is a high-temperature data retention failure mode, a long-term data retention failure mode, a cross-temperature effect failure mode, or a read disturb errors failure mode.

25. An apparatus, comprising:
means for receiving a data signal from a memory device;
means for detecting one or more errors in the data signal;
means for performing, responsive to detection of the one or more errors, a low-density parity check (LDPC) hard bit decoding on the data signal to identify respective hard bit read positions (HBRPs) for a plurality of threshold voltage levels associated with memory cells in the memory device;
means for identifying, with a machine learning model using the respective HBRPs, a failure mode of the memory device;
means for identifying a set of parameters for an LDPC soft bit decoding based on the failure mode,
wherein the set of parameters indicates a plurality of soft bit read positions (SBRPs) and a plurality of log likelihood ratio (LLR) values; and
means for performing the LDPC soft bit decoding on the data signal using the set of parameters.

26. The apparatus of claim 25, wherein the set of parameters is based on data derived using one or more memory devices subjected to stress conditions to simulate the failure mode.

27. The apparatus of claim 25, wherein the failure mode is a high-temperature data retention failure mode, a long-term data retention failure mode, a cross-temperature effect failure mode, or a read disturb errors failure mode.

28. The apparatus of claim 25, wherein the machine learning model is trained to classify multiple failure modes based on HBRP data.

29. A method, comprising:
obtaining threshold voltage data from a memory device subjected to stress conditions to simulate a failure mode;
identifying a plurality of hard bit read positions (HBRPs) for a plurality of voltage valleys defined by the threshold voltage data; and
training a machine learning model to classify the failure mode using the plurality of HBRPs labeled as being associated with the failure mode.

30. The method of claim 29, wherein the plurality of HBRPs minimize a raw bit error rate.

31. The method of claim 29, wherein identifying the plurality of HBRPs comprises:
iteratively adjusting an HBRP, of the plurality of HBRPs, in a voltage valley, of the plurality of voltage valleys, to obtain a minimum raw bit error rate.

32. The method of claim 29, further comprising:
identifying a plurality of soft bit read positions (SBRPs) for the plurality of voltage valleys; and
computing respective log likelihood ratio (LLR) values for a plurality of voltage bins defined by at least one of the plurality of HBRPs and at least one of the plurality of SBRPs,
wherein the plurality of SBRPs and the respective LLR values define a set of parameters for low-density parity check (LDPC) soft bit decoding.

33. The method of claim 32, wherein the plurality of SBRPs maximize mutual information.

34. The method of claim 32, further comprising:
generating a mapping of the set of parameters to the failure mode.

35. The method of claim 29, wherein training the machine learning model comprises:
training the machine learning model to classify multiple failure modes based on HBRP data.
